(19) United States
(12) Patent Application Publication
(10) Pub. No.: US 2016/0293809 A1
(43) Pub. Date: Oct. 6, 2016

(54) FLIP CHIP LIGHT EMITTING DIODE PACKAGE STRUCTURE

(71) Applicant: Genesis Photonics Inc., Tainan City (TW)

(72) Inventors: Jing-En Huang, Tainan City (TW); Shao-Ying Ting, Tainan City (TW); Chih-Ling Wu, New Taipei City (TW); Kuan-Yung Liao, Taipei City (TW); Yi-Ru Huang, Tainan City (TW); Yu-Yun Lo, Tainan City (TW)

(21) Appl. No.: 15/175,019

(22) Filed: Jun. 6, 2016

Related U.S. Application Data
(63) Continuation of application No. 14/513,215, filed on Oct. 14, 2014.

(30) Foreign Application Priority Data
Oct. 14, 2013 (TW) 102136992

(51) Int. Cl. H01L 33/50; H01L 33/58; H01L 33/54

(52) U.S. Cl. CPC H01L 33/505; H01L 33/54; H01L 33/58

(57) ABSTRACT

A flip chip light emitting diode package structure includes a package carrier, a light guiding unit and at least one light emitting unit. The light guiding unit and the light emitting unit are disposed on the package carrier, and the light emitting unit is located between the light guiding unit and the package carrier. A horizontal projection area of the light guiding unit is greater than that of the light emitting unit. The light emitting unit is adapted to emit a light beam, and the light beam enters the light guiding unit and emits from an upper surface of the light guiding unit away from the light emitting unit.

### CROSS-REFERENCE TO RELATED APPLICATION

This application is a continuation application of and claims the priority benefit of U.S. application Ser. No. 14/513,215, filed on Oct. 14, 2014, now pending. The prior application Ser. No. 14/513,215 claims the priority benefit of Taiwan application serial no. 102136992, filed on Oct. 14, 2013. The entirety of each of the above-mentioned patent applications is hereby incorporated by reference herein and made a part of this specification.

### BACKGROUND OF THE INVENTION

1. Field of the Invention

The invention relates to a package structure, and more particularly, to a flip chip light emitting diode package structure.

2. Description of Related Art

With the advances of the photovoltaic technology, technology of a new generation light source of light emitting diode (LED) which is to replace traditional incandescent light bulbs and fluorescent tubes becomes mature. Since LED has advantages such as low power consumption, small size, non-thermal luminescence, and environmental protection, the applications of LED are gradually extended.

In the traditional light emitting diode package structure, LED is disposed inside a package carrier, a fluorescent resin covers LED, and a package resin covers the fluorescent resin and the package carrier. Due to the fact that LED has specific light-exiting angles, light emitted from LED may be incident into the fluorescent resin and the package carrier at the specific angles. Accordingly, light emitting angles of the light emitting diode package structure are limited and may not have larger light-exiting angles.

### SUMMARY OF THE INVENTION

The invention provides a flip chip light emitting diode package structure, which may increase a range of light-exiting angles and brightness of a light emitting unit.

The flip chip light emitting diode package structure of the invention includes a package carrier, a light guiding unit, and at least one light emitting unit. The light guiding unit is disposed on the package carrier. The light emitting unit is disposed on the package carrier, and the light emitting unit is located between the light guiding unit and the package carrier. A horizontal projection area of the light guiding unit is greater than a horizontal projection area of the light emitting unit. The light emitting unit is adapted to emit a light beam. The light beam enters the light guiding unit and emits from an upper surface of the light guiding unit away from the light emitting unit.

In an embodiment of the invention, the light beam includes a first portion of the light beam and a second portion of the light beam. A first light-exiting direction of the first portion of the light beam parallels to a normal direction of the upper surface, and an angle between a second light-exiting direction of the second portion of the light beam and the normal direction of the upper surface is between 0 degree and 75 degrees.

In an embodiment of the invention, the light emitting unit includes a substrate, a first-type semiconductor layer, a light emitting layer, a second-type semiconductor layer, a first electrode, and a second electrode. The first-type semiconductor layer, the light emitting layer, and the second-type semiconductor layer are disposed sequentially on the substrate. The first electrode is electrically connected to the first-type semiconductor layer, and the second electrode is electrically connected to the second-type semiconductor layer.

In an embodiment of the invention, the package carrier has a component-disposing surface, a first pad, and a second pad. The first pad and the second pad are located on the component-disposing surface and are electrically connected to the first electrode and the second electrode of the light emitting unit, respectively.

In an embodiment of the invention, an exterior contour of the light guiding unit and an exterior contour of the substrate of the light emitting unit are nearly the same.

In an embodiment of the invention, a refractive index of the light guiding unit is less than or equal to a refractive index of the substrate of the light emitting unit.

In an embodiment of the invention, the package carrier comprises a plurality of conductive pillars which pass through the package carrier. The first electrode and the second electrode of the light emitting unit are electrically connected to the first pad and the second pad through the conductive pillars, respectively.

In an embodiment of the invention, a thickness of the light guiding unit is 0.1 times to 20 times a thickness of the substrate of the light emitting unit.

In an embodiment of the invention, a thickness of the light guiding unit is 1 times to 10 times a thickness of the substrate of the light emitting unit.

In an embodiment of the invention, the light guiding unit has a lower surface opposed to the upper surface, and at least one of the upper surface and the lower surface is a rough surface.

In an embodiment of the invention, a center-line average roughness of the rough surface is between 100 nm and 3000 nm.

In an embodiment of the invention, the rough surface is a patterned surface with a periodic arrangement.

In an embodiment of the invention, the light guiding unit is a sapphire tablet, a glass, or a flexible substrate.

In an embodiment of the invention, the flip chip light emitting diode package structure further includes an adhesive layer which is disposed between the light guiding unit and the package carrier. The adhesive layer covers periphery of the light emitting unit, and sides of the adhesive layer are trimmed aligned with sides of the light guiding unit.

In an embodiment of the invention, the adhesive layer is composed of materials with reflecting property.

In an embodiment of the invention, the flip chip light emitting diode package structure further includes an adhesive layer which is disposed between the light guiding unit and the package carrier. The adhesive layer covers entirely the light emitting unit, and sides of the adhesive layer are trimmed aligned with sides of the light guiding unit.

In an embodiment of the invention, the adhesive layer is a transparent material layer.

In an embodiment of the invention, the flip chip light emitting diode package structure further includes a wavelength conversion layer which is disposed on the package carrier and covers the light emitting unit and the light guiding unit.

In an embodiment of the invention, the flip chip light emitting diode package structure further includes a package resin which is disposed on the package carrier and covers the wavelength conversion layer and the package carrier.

In an embodiment of the invention, the at least one light emitting unit are a plurality of light emitting units. The light emitting units are electrically connected to the package carrier in series, in parallel, or in series-parallel.

In an embodiment of the invention, the horizontal projection area of the light guiding unit is 1.1 times to 5 times the horizontal projection area of the light emitting unit.

In an embodiment of the invention, the horizontal projection area of the light guiding unit is 1.1 times to 2 times the horizontal projection area of the light emitting unit.

According to the above, the flip chip light emitting diode package structure has a light guiding unit, wherein the horizontal projection area of the light guiding unit is greater than the horizontal projection area of the light emitting unit. Thus, the range of the light-exiting angles of the light beam emitted from the light emitting unit may be increased through the light guiding effect of the light guiding unit. Accordingly, the flip chip light emitting diode package structure in the present embodiment may have the wider light-exiting angles and the brightness thereof may be enhanced.

In order to make the aforementioned and other features and advantages of the invention comprehensible, embodiments accompanied with figures are described in detail below.

### BRIEF DESCRIPTION OF THE DRAWINGS

FIG. 1 illustrates a cross-sectional schematic diagram of a flip chip light emitting diode package structure according to an embodiment of the invention.

FIG. 2 illustrates a cross-sectional schematic diagram of a flip chip light emitting diode package structure according to another embodiment of the invention.

FIG. 3A illustrates a cross-sectional schematic diagram of a flip chip light emitting diode package structure according to another embodiment of the invention.

FIG. 3B illustrates a cross-sectional schematic diagram of a flip chip light emitting diode package structure according to another embodiment of the invention.

FIG. 4 illustrates a cross-sectional schematic diagram of a flip chip light emitting diode package structure according to another embodiment of the invention.

### DESCRIPTION OF EMBODIMENTS

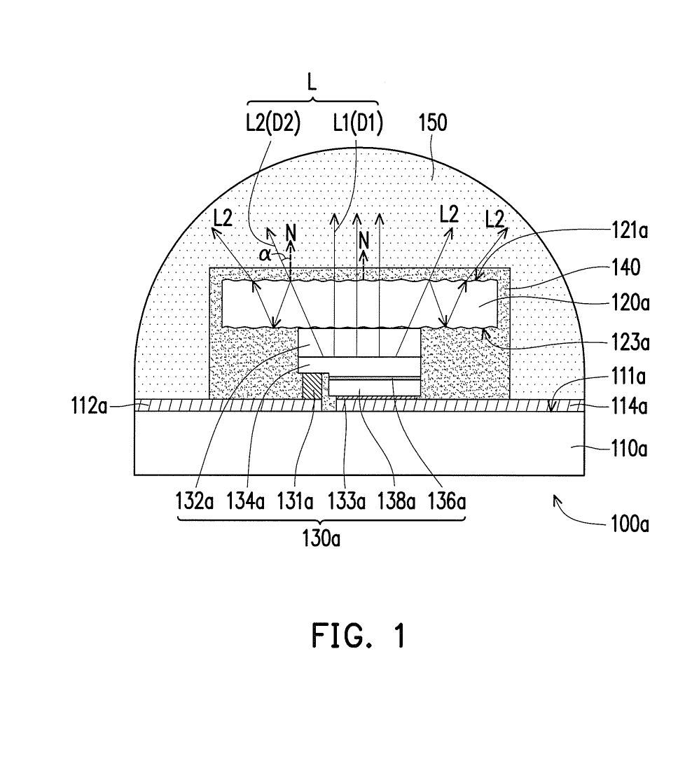

FIG. 1 illustrates a cross-sectional schematic diagram of a flip chip light emitting diode package structure according to an embodiment of the invention. Please refer to FIG. 1, in the present embodiment, a flip chip light emitting diode package structure 100a includes a package carrier 110a, a light guiding unit 120a, and at least one light emitting unit 130a (wherein it is schematically illustrated only one light emitting unit 130a in FIG. 1). The light guiding unit 120a is disposed on the package carrier 110a. The light emitting unit 130a is disposed on the package carrier 110a, and the light emitting unit 130a is located between the light guiding unit 120a and the package carrier 110a. A horizontal projection area of the light guiding unit 120a is greater than a horizontal projection area of the light emitting unit 130a. The light emitting unit 130a is adapted to emit a light beam L. The light beam L enters the light guiding unit 120a and emits from an upper surface 121a of the light guiding unit 120a which is away from light emitting unit 130a.

More specifically, the package carrier 110a of the present embodiment has a component-disposing surface 111a, a first pad 112a, and a second pad 114a. The first pad 112a and the second pad 114a are located on the component-disposing surface 111a. The light guiding unit 120a further has a lower surface 123a which is opposed to an upper surface of 121a. Specifically, at least one of the upper surface 121a and the lower surface 123a is a rough surface, wherein a center-line average roughness of the rough surface is between 100 nm and 3000 nm. Preferably, the rough surface is a patterned surface with a periodic arrangement. As shown in FIG. 1, both the upper surface 121a and the lower surface 123a of the light guiding unit 120a in the present embodiment are exemplified and illustrated as rough surfaces, but the invention is not limited thereto. In other embodiments not shown, only the upper surface or the lower surface of the light guiding unit may be a rough surface, which is also an employable technical aspect of the present invention without departing from the scope of the invention. Herein, the light guiding unit 120a is embodied as a sapphire tablet, a glass, a flexible substrate, or a patterned sapphire tablet, but the invention is not limited thereto.

Furthermore, the light emitting unit 130a of the present embodiment includes a substrate 132a, a first-type semiconductor layer 134a, a light emitting layer 136a, a second-type semiconductor layer 138a, a first electrode 131a, and a second electrode 133a. The first-type semiconductor layer 134a, the light emitting layer 136a, and the second-type semiconductor layer 138a are disposed sequentially on the substrate 132a. The first electrode 131a is electrically connected to the first-type semiconductor layer 134. The second electrode 133a is electrically connected to the second-type semiconductor layer 138a. As shown in FIG. 1, the first electrode 131a and the second electrode 133a of the light emitting unit 130a are direct structurally and electrically connected to the first pad 112a and the second pad 114a of the package carrier 110a, respectively. Herein, the light emitting unit 130a is such as a flip chip light emitting diode.

Moreover, please refer again to FIG. 1, an exterior contour of the light guiding unit 120a in the present embodiment and an exterior contour of the substrate 132a of the light emitting unit 130a are nearly the same. Accordingly, the light-exiting angles of each facing of the light emitting unit 130a may be equivalently increased, which may avoid problem of uneven brightness. In addition, a thickness of the light guiding unit 120a in the present embodiment is 0.1 times to 20 times a thickness of the substrate 132a of the light emitting unit 130a. If the ratio of the thickness is less than 0.1 times, then a light guiding effect of the light guiding unit 120a may be poor, and thus the light-exiting angles of the light emitting unit 130a may not be increased. If the ratio of the thickness is greater than 20 times, then a heat accumulation phenomenon may be produced inside the light guiding unit 120a, which may lead to heating of the light emitting diode package structure 100a and thus the life thereof may be shortened. Preferably, the thickness of the light guiding unit 120a is 1 times to 10 times the thickness of the substrate 132a of the light emitting unit 130a. Furthermore, the horizontal projection area of the light guiding unit 120a in the present embodiment is 1.1 times to 5 times the horizontal projection area of the light emitting unit 130a. If the ratio of the area is less than 1.1 times, then the light guiding effect of the light guiding unit 120a may be poor, and thus the light-exiting angles of the light emitting unit 130a may not be increased. If the ratio of the area is greater than 5 times, then the light guiding unit 120a may not be easily fixed on the package carrier110. Preferably, the horizontal projection area of the light guiding unit 120a is 1.1 times to 2 times the horizontal projection area of the light emitting unit 130a. On the other hand, a refractive index of the light guiding unit 120a in the present embodiment is less than or equal to a refractive index of the substrate 132a of the light emitting unit 130a.

On the other hand, the flip chip light emitting diode package structure 100a in the present embodiment may further include a wavelength conversion layer 140 and a package resin 150. The wavelength conversion layer 140 is disposed on the package carrier 110a and covers the light emitting unit 130a and the light guiding unit 120a directly. The package resin 150 is disposed on the package carrier 110a and covers the wavelength conversion layer 140 and a first pad 112a and a second pad 114a of the package carrier 110a. As shown in FIG. 1, the light beam L emitted from the light emitting unit 130a in the present embodiment may be distinguished as a first portion of the light beam L1 and a second portion of the light beam L2. A first light-exiting direction D1 of the first portion of the light beam L1 parallels to a normal direction N of an upper surface 121a. An angle a between a second light-exiting direction D2 of the second portion of the light beam L2 and the normal direction N of the upper surface 121a is between 0 degree and 75 degrees 0 degree. That is, the first portion of the light beam Ll from the light emitting unit 130a passes directly through the light guiding unit 120a to exit. The second portion of the light beam L2 exits through the light guiding effect of the light guiding unit 120a along the direction not parallels to the normal direction N of the upper surface 121a. Accordingly, the light-exiting angles of the light emitting unit 130a may be effectively increased.

The flip chip light emitting diode package structure 100a in the present embodiment has the light guiding unit 120a, wherein the horizontal projection area of the light guiding unit 120a is greater than the horizontal projection area of the light emitting unit 130a. Therefore, the range of the light-exiting angles of the light beam L emitted from the light emitting unit 130a may be increased through the light guiding unit 120a. Accordingly, the flip chip light emitting diode package structure 100a in the present embodiment may have wider light-exiting angles and the brightness thereof may be enhanced. Moreover, the upper surface 121a and the lower surface 123a of the light guiding unit 120a in the present embodiment are both rough surfaces, which may contribute to refracting and scattering the light beam L emitted from the light emitting unit 130a so as to improve light extraction efficiency.

It should be noted that, the reference numerals and part of the contents in the above embodiment are used in the following embodiments, wherein the same or similar components are represented as the same reference numerals, and description of the same technical contents are omitted. Please refer to the above embodiment for the omitted part of description, which may not be illustrated again in the following embodiments.

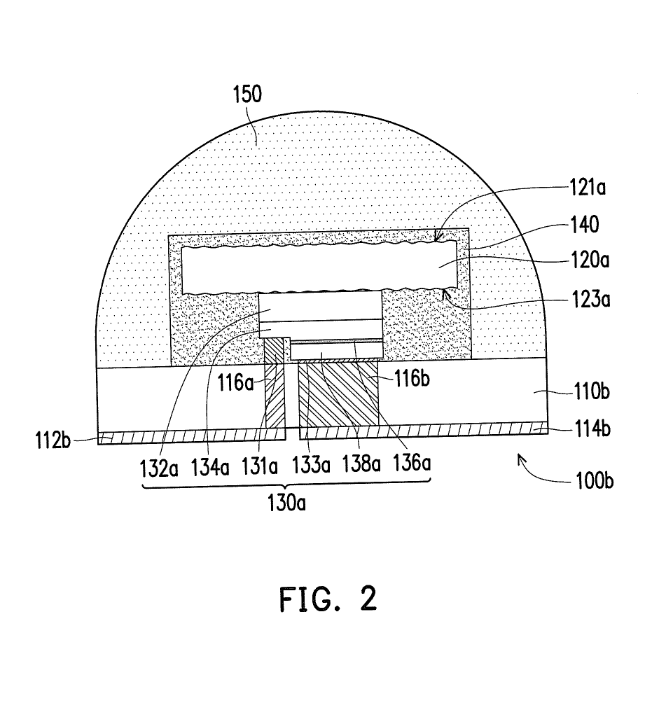

FIG. 2 illustrates a cross-sectional schematic diagram of a flip chip light emitting diode package structure according to another embodiment of the invention. Please refer to FIG. 2. A flip chip light emitting diode package structure 100b is similar to the flip chip light emitting diode package structure 100a shown in FIG. 1, wherein the main difference therebetween is that the package carrier 110b in the present embodiment includes a plurality of conductive pillars 116b (wherein it is schematically illustrated only two conductive pillars 116b in FIG. 2). The conductive pillar 116b passes through a package carrier 110b, wherein the first electrode 131a and the second electrode 133a of the light emitting unit 130a are electrically connected to a first pad 112b and a second pad 114b through the conductive pillar 116b, respectively.

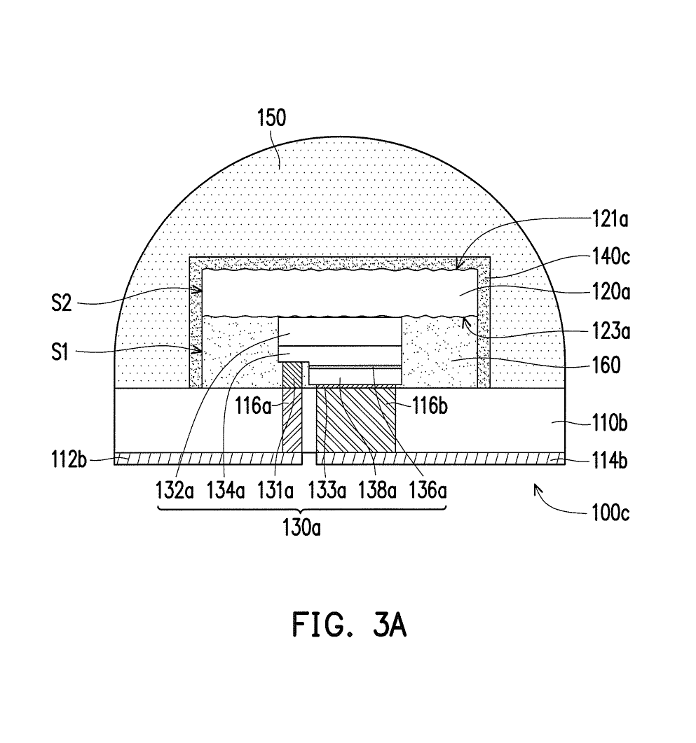

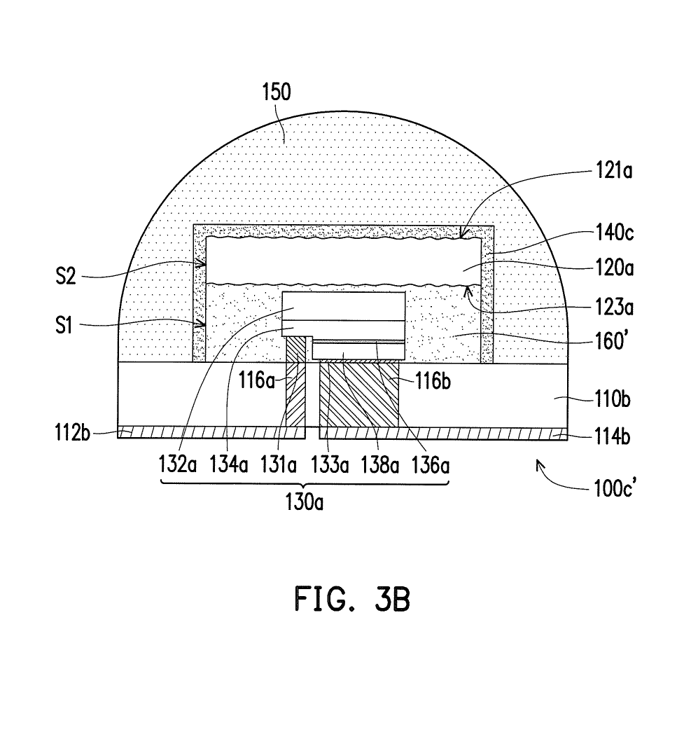

FIG. 3A illustrates a cross-sectional schematic diagram of a flip chip light emitting diode package structure according to another embodiment of the invention. Please refer to FIG. 3A. A flip chip light emitting diode package structure 100c in the present embodiment is similar to the flip chip light emitting diode package structure 100b shown in FIG. 2, wherein the main difference therebetween is that the flip chip light emitting diode package structure 100c in the present embodiment further includes an adhesive layer 160. The adhesive layer 160 is disposed between the light guiding unit 120a and the package carrier 110b so as to enhance adhesion between the light guiding unit 120a and the package carrier110b. In addition, the adhesive layer 160 may be composed of materials with reflecting property such as silicone. As shown in FIG. 3A, the adhesive layer 160 in the present embodiment covers periphery of the light emitting unit 130a, and a side S1 of the adhesive layer 160 is trimmed aligned with a side S2 of the light guiding unit 120a.

In another embodiment, please refer to FIG. 3B. A flip chip light emitting diode package structure 100c′ is similar to the flip chip light emitting diode package structure 100c shown in FIG. 3A, wherein the main difference therebetween is that a adhesive layer 160′ may cover entirely the light emitting unit 130a, meaning that the adhesive layer 160′ covers the surface of the substrate 132a of the light emitting unit 130a and the periphery of the light emitting unit 130a. In this case, the adhesive layer 160′ is a transparent material layer. The above embodiments still belong to the employable technical aspect of the present invention without departing from the scope of the invention.

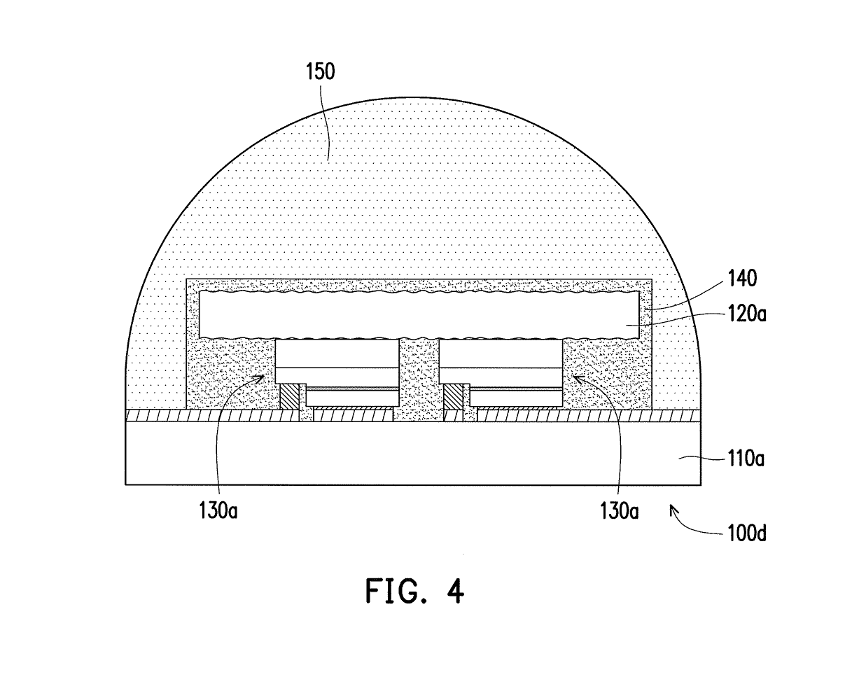

FIG. 4 illustrates a cross-sectional schematic diagram of a flip chip light emitting diode package structure according to another embodiment of the invention. Please refer to FIG. 4. A flip chip light emitting diode package structure 100d in the present embodiment is similar to the flip chip light emitting diode package structure 100a shown in FIG. 1, wherein the main difference therebetween is that the flip chip light emitting diode package structure 100d in the present embodiment includes a plurality of the light emitting units 130a (wherein it is schematically illustrated two light emitting units 130a in FIG. 4). The light emitting units 130a are electrically connected to the package carrier 110a in series, in parallel, or in series-parallel. In other words, the flip chip light emitting diode package structure 100d in the present embodiment is a flip chip light emitting diode package structure with multi-chips.

According to the above, the flip chip light emitting diode package structure has a light guiding unit, wherein the horizontal projection area of the light guiding unit is greater than the horizontal projection area of the light emitting unit. Thus, the range of the light-exiting angles of the light beam emitted from the light emitting unit may be increased through the light guiding effect of the light guiding unit. Accordingly, the flip chip light emitting diode package structure in the present embodiment may have the wider light-exiting angles and the brightness thereof may be enhanced.

It will be apparent to those skilled in the art that various modifications and variations can be made to the structure of the disclosed embodiments without departing from the scope or spirit of the invention. In view of the foregoing, it is intended that the disclosure cover modifications and variations of this specification provided they fall within the scope of the following claims and their equivalents.

What is claimed is:

1. A flip chip light emitting diode (LED) package structure, comprising:
at least one light emitting unit comprising a first-type semiconductor layer, a light emitting layer and a second-type semiconductor layer disposed sequentially on a first side of a substrate and having electrodes electrically connected to the first-type semiconductor and the second-type semiconductor, respectively;
a light transmissive member comprising a light guiding unit and a wavelength conversion layer, the light transmissive member disposed over the light emitting unit; and
an adhesive layer covering the light emitting unit and at least exposing the electrodes, wherein the light guiding unit and the wavelength conversion layer have a rough interface.

2. The flip chip LED package structure as claimed in claim 1, further comprising:
a package carrier, carrying and coupled to the light emitting unit.

3. The flip chip LED package structure as claimed in claim 2, wherein the electrodes of the light emitting unit are electrically connected to pads of the package carrier, respectively.

4. The flip chip LED package structure as claimed in claim 3, wherein the package carrier comprises inner conductive pillars through which the electrodes of the light emitting unit are electrically connected to the pads of the package carrier.

5. The flip chip LED package structure as claimed in claim 2, further comprising:
a package resin, disposed on the package carrier and covering the wavelength conversion layer and the package carrier.

6. The flip chip light emitting diode package structure as claimed in claim 2, wherein the quantity of the at least one light emitting unit is two or more, the light emitting units are electrically connected in series, in parallel, or in series-parallel.

7. A flip chip light emitting diode (LED) package structure, comprising:
a light guiding unit having a wavelength conversion layer adhering thereon and an rough interface formed therebetween;
at least one light emitting unit attached to the light guiding unit and the wavelength conversion layer, wherein the light emitting unit has a forward light emitting surface facing to the rough interface and has electrodes arranged on one surface opposite to the forward light emitting surface;
an adhesive layer disposed between the light emitting unit and the light guiding unit; and
a package carrier canying and coupled to the light emitting unit.

8. The flip chip LED package structure as claimed in claim 7, further comprising:
a package resin, disposed on the package carrier and encapsulating the light emitting unit, the adhesive layer and the light guiding unit with the wavelength conversion layer adhering thereon.

9. The flip chip LED package structure as claimed in claim 7, wherein the electrodes of the light emitting unit are electrically connected to pads of the package carrier, respectively.

10. The flip chip LED package structure as claimed in claim 9, wherein the package carrier comprises inner conductive pillars through which the electrodes of the light emitting unit are electrically connected to the pads of the package carrier.

11. The flip chip light emitting diode package structure as claimed in claim 7, wherein the quantity of the at least one light emitting unit is two or more, the light emitting units are electrically connected in series, in parallel, or in series-parallel.

12. A flip chip light emitting diode (LED) package structure, comprising:
a package carrier;
at least one light emitting unit having electrodes on a surface thereof, the light emitting unit disposed on the package carrier;
a light transmissive member, having a light guiding unit and a wavelength conversion layer, disposed over the at least one light emitting unit; and
an adhesive layer disposed between the light transmissive member and the at least one light emitting unit,
wherein the light guiding unit and the wavelength conversion layer have an rough interface therebetween.

13. The flip chip LED package structure as claimed in claim 12, further comprising:
a package resin, disposed on the package carrier and encapsulating the light emitting unit and the light transmissive member.

14. The flip chip LED package structure as claimed in claim 12, wherein the electrodes of the light emitting unit are electrically connected to pads of the package carrier, respectively.

15. The flip chip LED package structure as claimed in claim 14, wherein the package carrier comprises inner conductive pillars through which the electrodes of the light emitting unit are electrically connected to the pads of the package carrier.

16. The flip chip light emitting diode package structure as claimed in claim 12, wherein the quantity of the at least one light emitting unit is two or more, the light emitting units are electrically connected in series, in parallel, or in series-parallel.
